(19) United States
(12) Patent Application Publication
(10) Pub. No.: US 2023/0369534 A1
(43) Pub. Date: Nov. 16, 2023

(54) SEMICONDUCTOR LIGHT EMITTING ELEMENT AND METHOD FOR MANUFACTURING SEMICONDUCTOR LIGHT EMITTING ELEMENT

(71) Applicants: KOITO MANUFACTURING CO., LTD., Tokyo (JP); MEIJO UNIVERSITY, Nagoya-shi, Aichi (JP)

(72) Inventors: Satoshi KAMIYAMA, Nagoya-shi, Aichi (JP); Tetsuya TAKEUCHI, Nagoya-shi, Aichi (JP); Motoaki lWAYA, Nagoya-shi, Aichi (JP); Isamu AKASAKI, Nagoya-shi, Aichi (JP); Weifang LU, Nagoya-shi, Aichi (JP); Kazuma ITO, Nagoya-shi, Aichi (JP); Naoki SONE, Shizuoka-shi, Shizuoka (JP)

(73) Assignees: KOITO MANUFACTURING CO., LTD., Tokyo (JP); MEIJO UNIVERSITY, Nagoya-shi, Aichi (JP)

(21) Appl. No.: 18/043,220

(22) PCT Filed: Aug. 25, 2021
(86) PCT No.: PCT/JP2021/031199

§ 371 Date: Feb. 27, 2023

(30) Foreign Application Priority Data
Aug. 31, 2020 (JP) 2020-145488

(51) Int. Cl. H01L 33/02; H01L 33/08; H01L 33/00; H01L 33/24

(52) U.S. Cl. CPC H01L 33/025; H01L 33/08; H01L 33/007; H01L 33/24; H01L 33/325

(57) ABSTRACT

A semiconductor light emitting element includes: a growth substrate; a mask formed on the growth substrate; and a columnar semiconductor layer grown from at least one opening that is provided in the mask. The columnar semiconductor layer includes an n-type nanowire layer formed at a center thereof, an active layer formed on an outer periphery of the n-type nanowire layer, and a p-type semiconductor layer formed on an outer periphery of the active layer. An opening ratio of the opening is 0.1% or more and 5.0% or less, and a light emission wavelength is 480 nm or more.

### TECHNICAL FIELD

The present disclosure relates to a semiconductor light emitting element and a method for manufacturing a semiconductor light emitting element.

### BACKGROUND ART

In recent years, a crystal growth method for a nitride-based semiconductor has rapidly progressed, and blue and green light emitting elements of high luminance using the material have been put into practical use. By combining a red light emitting element present in related art with the blue light emitting element and the green light emitting element, all of three primary colors of light are obtained, and a full color display device can also be implemented. White light can also be obtained when all of the three primary colors of light are mixed, and application to an illumination device is also possible.

A semiconductor light emitting element used for a light source for illumination is desirably capable of achieving high energy conversion efficiency and high light output in a high current density region, and is desirably stable in light distribution characteristic of emitted light. In order to solve these problems, a semiconductor light emitting element in which an n-type nanowire core, an active layer, and a p-type layer are formed on a semiconductor substrate has been proposed in Patent Literature 1.

The semiconductor light emitting element in which the active layer is formed on an outer periphery of the nanowire core, which is disclosed in Patent Literature 1, has fewer crystal defects and threading dislocations than those of a semiconductor light emitting element in which an active layer is formed on an entire surface of a sapphire substrate, so that a high-quality crystal can be obtained, and improvement in external quantum efficiency at a high current density can be achieved since growth can be performed on an m-plane. In the semiconductor light emitting element using the nanowire core in Patent Literature 1, the active layer can be formed of the high-quality crystal, so that it is expected that an In composition in the active layer is increased to achieve an increase in wavelength.

### CITATION LIST

### Patent Literature

Patent Literature 1: JP2019-012744A

### SUMMARY OF INVENTION

### Technical Problem

In the semiconductor light emitting element in related art, a ratio of In incorporated into the active layer is increased by increasing a diameter of the nanowire core, thereby achieving the increase in wavelength. However, it is difficult to sufficiently increase the ratio of In incorporated into the active layer, and it is difficult to emit light at 480 nm or more such as a blue-green, green, or red wavelength with high reproducibility.

An object of the present disclosure is to provide a semiconductor light emitting element and a method for manufacturing a semiconductor light emitting element capable of emitting light at 480 nm or more with high reproducibility by increasing a ratio of In incorporated into an active layer that is formed on an outer periphery of a nanowire.

### Solution to Problem

In order to solve the above problems, a semiconductor light emitting element according to the present disclosure is a semiconductor light emitting element including: a growth substrate; a mask formed on the growth substrate; and a columnar semiconductor layer grown from at least one opening that is provided in the mask. The columnar semiconductor layer includes an n-type nanowire layer formed at a center thereof, an active layer formed on an outer periphery of the n-type nanowire layer, and a p-type semiconductor layer formed on an outer periphery of the active layer. An opening ratio of the opening is 0.1% or more and 5.0% or less, and a light emission wavelength is 480 nm or more.

In such a semiconductor light emitting element according to the present disclosure, the opening ratio of the opening formed in the mask is set in a range of 0.1% or more and 5.0% or less, so that a ratio of In incorporated into the active layer can be increased by controlling a height, a diameter, and a crystal growth plane of the n-type nanowire layer under the same growth conditions, and light can be emitted at 480 nm or more with high reproducibility.

In order to solve the above problems, a semiconductor light emitting element according to the present disclosure is a semiconductor light emitting element including: a growth substrate; a mask formed on the growth substrate; and a columnar semiconductor layer grown from each of openings that are provided in the mask. The columnar semiconductor layer includes an n-type nanowire layer formed at a center thereof, an active layer formed on an outer periphery of the n-type nanowire layer, and a p-type semiconductor layer formed on an outer periphery of the active layer. In a first region of the growth substrate, an opening ratio of the opening is 0.1% or more and 5.0% or less, and a light emission wavelength is 480 nm or more. In a second region of the growth substrate, an opening ratio of the opening is more than 5.0%, and a light emission wavelength is less than 480 nm.

In order to solve the above problems, a semiconductor light emitting element according to the present disclosure is a semiconductor light emitting element including: a growth substrate; a mask formed on the growth substrate; and a columnar semiconductor layer grown from each of openings that are provided in the mask. The columnar semiconductor layer includes an n-type nanowire layer formed at a center thereof, an active layer formed on an outer periphery of the n-type nanowire layer, and a p-type semiconductor layer formed on an outer periphery of the active layer. In a first region of the growth substrate, an opening ratio of the opening is a first opening ratio. In a second region of the growth substrate, an opening ratio of the opening is a second opening ratio. The first opening ratio is smaller than the second opening ratio, and a light emission wavelength in the first region is longer than that in the second region.

In order to solve the above problems, a semiconductor light emitting element according to the present disclosure is a semiconductor light emitting element including: a growth substrate; a mask formed on the growth substrate; and a columnar semiconductor layer grown from each of openings that are provided in the mask. The columnar semiconductor layer includes an n-type nanowire layer formed at a center thereof, an active layer formed on an outer periphery of the n-type nanowire layer, and a p-type semiconductor layer formed on an outer periphery of the active layer. The openings in a first region and the openings in a second region of the growth substrate are the same in opening ratio and different in opening diameter and pitch, and the first region and the second region are the same in height of the n-type nanowire layer.

In order to solve the above problems, a method for manufacturing a semiconductor light emitting element according to the present disclosure includes: a mask step of forming, on a growth substrate, a mask layer including an opening; and a growth step of forming a columnar semiconductor layer in the opening by using selective growth. The growth step includes a step of forming an n-type nanowire layer, a step of forming an active layer on an outer side of the n-type nanowire layer, and a step of forming a p-type semiconductor layer on an outer side of the active layer. In the mask step, an opening ratio of the opening is set in a range of 0.1% or more and 5.0% or less.

### ADVANTAGEOUS EFFECTS OF INVENTION

According to the present disclosure, it is possible to provide a semiconductor light emitting element and a method for manufacturing a semiconductor light emitting element capable of emitting light at 480 nm or more with high reproducibility by increasing a ratio of In incorporated into an active layer that is formed on an outer periphery of a nanowire.

### BRIEF DESCRIPTION OF DRAWINGS

FIG. 1 is a schematic view showing a semiconductor light emitting element 10 according to a first embodiment.

FIGS. 2A to 2E are schematic views showing a method for manufacturing the semiconductor light emitting element 10, FIG. 2A shows a mask formation step, FIG. 2B shows a nanowire growth step, FIG. 2C shows a growth step, FIG. 2D shows a removal step, and FIG. 2E shows an electrode formation step.

FIG. 3 is a schematic plan view showing a shape of a mask 13 formed in a light emitting region on a growth substrate 11.

FIGS. 4A to 4C are schematic views showing a case where a ratio of a radius r and a pitch p of openings 13a is constant and the radius r is changed, an upper part shows schematic plan views, and a lower part shows schematic sectional views.

FIGS. 5A to 5C are schematic views showing a case where the pitch p of the openings 13a is constant and the radius r is changed, an upper part shows schematic plan views, and a lower part shows schematic sectional views.

FIGS. 6A to 6C are schematic views showing a case where the pitch p and the radius r of the openings 13a are changed, an upper part shows schematic plan views, and a lower part shows schematic sectional views.

FIG. 7A and FIG. 7B are schematic sectional views each showing a facet constituting a surface of an n-type nanowire layer 14, FIG. 7A shows a case where a top surface is a c-plane, and FIG. 7B shows a case where the top surface is an r-plane.

FIGS. 8A to 8C are schematic views showing a case where the pitch p of the openings 13a is constant, the radius r is changed, and an r-plane facet is exposed as a top surface, an upper part shows schematic plan views, and a lower part shows schematic sectional views.

FIG. 9 is a graph showing experimental results of Manufacturing Examples 1 to 10, and shows a relationship between an opening ratio of the openings 13a and a light emission wavelength.

FIG. 10 is schematic views showing light emitting regions of the semiconductor light emitting element 10 according to a second embodiment, an upper part in FIG. 10 is a schematic plan view, and a lower part in FIG. 10 is a schematic sectional view.

FIG. 11 is SEM images showing crystal growth for the n-type nanowire layer 14 when the openings 13a having different opening diameters are formed in a plurality of regions on the same growth substrate 11.

FIG. 12 is SEM images and results of cathode luminescence measurement showing a state where a GaInN/GaN multiple quantum well structure is formed as an active layer 15 on an outer periphery of the n-type nanowire layer 14.

FIG. 13 is SEM images and a result of cathode luminescence measurement when a GaN barrier layer in the active layer 15 is grown at 800° C.

FIG. 14 is SEM images and results of cathode luminescence mapping when a GaInN well layer in the active layer 15 is grown at 730° C.

FIG. 15 is graphs showing normalized CL intensities when growth temperatures of the GaInN well layer are 750° C., 730° C., and 710° C.

### DESCRIPTION OF EMBODIMENTS

### First Embodiment

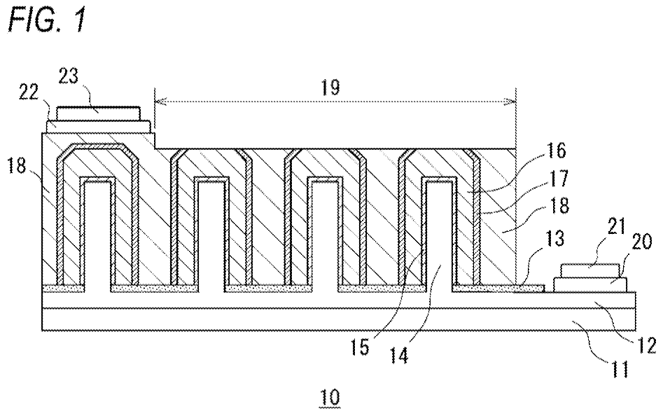

Hereinafter, embodiments of the present disclosure will be described in detail with reference to drawings. The same or equivalent components, members, and processing shown in the drawings are denoted by the same reference numerals, and repeated description thereof will be omitted as appropriate. FIG. 1 is a schematic view showing a semiconductor light emitting element 10 according to a first embodiment.

As shown in FIG. 1, the semiconductor light emitting element 10 includes a growth substrate 11, an underlying layer 12, a mask 13, an n-type nanowire layer 14, an active layer 15, a p-type semiconductor layer 16, a tunnel junction layer 17, and a buried semiconductor layer 18. Here, the n-type nanowire layer 14, the active layer 15, the p-type semiconductor layer 16, and the tunnel junction layer 17 are selectively grown in a direction perpendicular to the growth substrate 11 to have a columnar shape, and constitute a columnar semiconductor layer in the present disclosure. A removed region 19 in which a portion from the buried semiconductor layer 18 to an upper surface of the tunnel junction layer 17 is removed is formed in a part of a plurality of columnar semiconductor layers.

As shown in FIG. 1, in a part of the semiconductor light emitting element 10, the underlying layer 12 is exposed, and cathode electrodes 20 and 21 are formed on the underlying layer 12. The buried semiconductor layer 18 is left in a partial region on a top of the columnar semiconductor layer, and anode electrodes 22 and 23 are formed on the buried semiconductor layer 18 in the region. As described above, in a region where the anode electrodes 22 and 23 are not formed, the buried semiconductor layer 18 and the tunnel junction layer 17 are removed until the p-type semiconductor layer 16 is partially exposed, so that the removed region 19 is formed. Here, exposure of the p-type semiconductor layer 16 means that the p-type semiconductor layer 16 is exposed after all of semiconductor layers constituting the semiconductor light emitting element 10 are formed, and a passivation film, a transparent electrode, an insulating film, or the like may be formed in a subsequent step as described later.

The growth substrate 11 is a substantially flat plate-shaped member made of a material on which a crystal of a semiconductor material can be grown, and the mask 13 is formed on a main surface side of the growth substrate 11 . The growth substrate 11 may be made of a single material, or may be formed by growing a plurality of semiconductor layers such as a buffer layer on a single crystal substrate. The growth substrate 11 may be any substrate as long as the growth substrate 11 is a single crystal substrate made of a material over which a semiconductor single crystal layer is grown with a buffer layer interposed therebetween. The growth substrate 11 is preferably a c-plane sapphire substrate when the semiconductor light emitting element 10 is made of a nitride-based semiconductor, and may also be another heterogeneous substrate made of Si or the like. In order to enable laser oscillation, a c-plane GaN substrate on which a resonator plane is easily formed by cleavage may also be used. The buffer layer is a layer which is formed between the single crystal substrate and the underlying layer 12 to relax lattice mismatch between the single crystal substrate and the underlying layer 12. When the c-plane sapphire substrate is used as the single crystal substrate, as the material, GaN is preferably used, and AlN, AlGaN, or the like may also be used.

The underlying layer 12 is a single crystal semiconductor layer formed on the growth substrate 11 or the buffer layer, and is preferably formed of a plurality of layers in which non-doped GaN is formed with a thickness of several micrometers and which include an n-type semiconductor layer such as an n-type contact layer on the non-doped GaN. The n-type contact layer is a semiconductor layer doped with an n-type impurity, and examples of the n-type contact layer include n-type Al_{0.05}Ga_{0.95}N doped with Si. As shown in FIG. 1, a part of the underlying layer 12 is exposed, so that the cathode electrodes 20 and 21 are formed.

The mask 13 is a layer which is made of a dielectric material and formed on a surface of the underlying layer 12. As a material of which the mask 13 is made, a material that makes a crystal of a semiconductor difficult to be grown from the mask 13 is selected, and SiO₂, SiNₓ, Al₂O₃, and the like are, for example, preferred. A plurality of openings, which will be described later, are formed in the mask 13, and a semiconductor layer can be grown from the underlying layer 12 partially exposed from the openings.

The columnar semiconductor layer is a semiconductor layer formed by crystal growth in a respective one of the openings that are provided in the mask 13, and the semiconductor layer having a substantially columnar shape is disposed upright and formed so as to be vertical with respect to a main surface of the growth substrate 11. Such a columnar semiconductor layer can be obtained by setting appropriate growth conditions according to a semiconductor material of which the columnar semiconductor layer is made, and performing selective growth in which growth is performed in a specific crystal plane orientation. In an example shown in FIG. 1, the plurality of openings are two-dimensionally and periodically formed in the mask 13, so that the columnar semiconductor layers are also two-dimensionally and periodically formed above the growth substrate 11.

Each n-type nanowire layer 14 is a semiconductor layer having a columnar shape which is selectively grown on the underlying layer 12 exposed from a respective one of the openings of the mask 13, and is made of, for example, GaN doped with an n-type impurity. When GaN is used as the n-type nanowire layer 14, the n-type nanowire layer 14 selectively grown on a c-plane of the underlying layer 12 has a substantially hexagonal column shape in which six m-planes are formed as facets. In FIG. 1, the n-type nanowire layer 14 appears to be grown only in a region where the opening is formed, but actually, crystal growth proceeds also on the mask 13 due to lateral growth, so that a hexagonal column enlarged around the opening is formed. For example, when the opening is formed as a circle having a diameter of about 150 nm, it is possible to form the n-type nanowire layer 14 having the hexagonal column shape whose height is about 1 μm to 2 μm and whose bottom surface has a hexagonal shape that is inscribed in a circle having a diameter of about 240 nm.

The active layer 15 is a semiconductor layer grown on an outer periphery of the n-type nanowire layer 14. Examples of the active layer 15 include a multiple quantum well active layer in which a GaInN quantum well layer having a thickness of 5 nm and a GaN barrier layer having a thickness of 10 nm are stacked in five cycles. Here, the multiple quantum well active layer is exemplified, but the active layer 15 may be a single quantum well structure or a bulk active layer. Since the active layer 15 is formed on a side surface and an upper surface of the n-type nanowire layer 14, an area of the active layer 15 can be ensured. A light emission wavelength of the semiconductor light emitting element 10 increases as a ratio of In incorporated into an active layer increases, and the light emission wavelength can be 480 nm or more when an In composition ratio is set to 0.10 or more. When the In composition ratio is set to 0.12 or more, the light emission wavelength can be 500 nm or more.

The p-type semiconductor layer 16 is a semiconductor layer grown on an outer periphery of the active layer 15, and is made of, for example, GaN doped with a p-type impurity. Since the p-type semiconductor layer 16 is formed on a side surface and an upper surface of the active layer 15, a double heterostructure is formed by the n-type nanowire layer 14, the active layer 15, and the p-type semiconductor layer 16, and carriers can be favorably confined in the active layer 15 to improve a probability of light emission recombination. In the semiconductor light emitting element 10 according to the present embodiment, when the removed region 19 is formed, removal is performed up to a middle of the p-type semiconductor layer 16 by etching. Therefore, in order to prevent the etching from reaching the active layer 15, it is preferable to increase a film thickness of the p-type semiconductor layer 16 grown on the upper surface of the active layer 15, and it is preferable to set the film thickness of the p-type semiconductor layer 16 to, for example, 200 nm or more.

The tunnel junction layer 17 is a semiconductor layer grown on an outer periphery of the p-type semiconductor layer 16, and includes, for example, a two-layer structure in which a p+ layer doped with a p-type impurity at a high concentration on an inner side and an n+ layer doped with an n-type impurity at a high concentration on an outer side are sequentially grown.

As the p+ layer, which is a semiconductor layer doped with the p-type impurity at the high concentration, GaN having a thickness of 5 nm and a Mg concentration of 2×10²⁰ cm⁻³ can be, for example, used. As the n+ layer, GaN having a thickness of 10 nm and a Si concentration of 2×10²⁰ cm⁻³ can be, for example, used. Since a tunnel junction is formed by the p+ layer and the n+ layer, the two layers of the p+ layer and the n+ layer constitute the tunnel junction layer 17 in the present disclosure.

The buried semiconductor layer 18 is a semiconductor layer which is formed so as to cover an upper surface and a side surface of the columnar semiconductor layer and to cover the mask 13. As shown in FIG. 1, on a top of the columnar semiconductor layer in a region where the anode electrodes 22 and 23 are formed, the buried semiconductor layer 18 also covers the tunnel junction layer 17. On a top of the columnar semiconductor layer in the removed region 19 where the anode electrodes 22 and 23 are not formed, the buried semiconductor layer 18 and the tunnel junction layer 17 are removed to expose an upper portion of the p-type semiconductor layer 16, and the buried semiconductor layer 18 is in contact with a side surface of the tunnel junction layer 17 as shown in FIG. 1.

The removed region 19 is a region in which in at least a part of the columnar semiconductor layer, a portion from the buried semiconductor layer 18 to a part of the tunnel junction layer 17 is removed. In the example shown in FIG. 1, an example in which the tunnel junction layer 17 is removed is shown, but any removal may be performed as long as at least a part of the p-type semiconductor layer 16 is exposed, and removal may be performed up to the upper portion of the p-type semiconductor layer 16. FIG. 1 shows an example in which the removed region 19 is formed collectively for the plurality of columnar semiconductor layers, but the removed regions 19 may be provided individually for the plurality of columnar semiconductor layers.

The cathode electrodes 20 and 21 are electrodes formed in a region where the underlying layer 12 is exposed, and are formed by a laminated structure of a pad electrode and a metal material which is in ohmic contact with an outermost surface of the underlying layer 12. The anode electrodes 22 and 23 are electrodes formed on a part of the buried semiconductor layer 18, and are formed by a laminated structure of a pad electrode and a metal material which is in ohmic contact with an outermost surface of the buried semiconductor layer 18. Although not shown in FIG. 1, a known structure such as covering a surface of the semiconductor light emitting element 10 with the passivation film may be applied as necessary. The transparent electrode obtained by extending the anode electrode 22 may be formed in the entire removed region 19.

When the light emission wavelength of the semiconductor light emitting element 10 is to be increased, it is necessary to increase an InN mole fraction in the active layer 15. For example, when a diameter of a circumscribed circle of the n-type nanowire layer 14 is 300 nm, it is necessary to use Ga_{0.6}In_{0.4}N having a red active layer composition, but compressive stress increases as the InN mole fraction increases, and misfit dislocations may occur. In order to avoid occurrence of the misfit dislocations, it is also possible to reduce a film thickness of a Ga_{0.6}In_{0.4}N well layer or to use GaInN as a material of which the n-type nanowire layer 14 is made. Similarly, when the wavelength of the semiconductor light emitting element 10 is to be shortened, it is also possible to use AlGaN as the n-type nanowire layer 14 or to change the well layer and the barrier layer of the active layer 15 to AlGaN having different compositions.

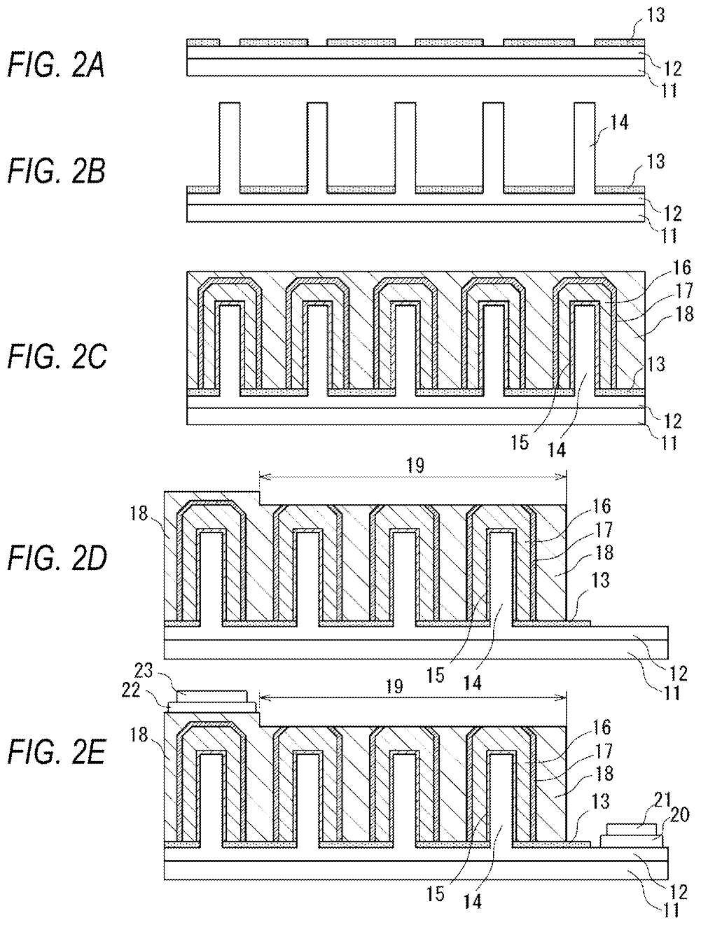

FIGS. 2A to 2E are schematic views showing a method for manufacturing the semiconductor light emitting element 10, FIG. 2A shows a mask formation step, FIG. 2B shows a nanowire growth step, FIG. 2C shows a growth step, FIG. 2D shows a removal step, and FIG. 2E shows an electrode formation step.

First, in the mask step shown in FIG. 2A, the buffer layer made of GaN, and the underlying layer 12 made of GaN and AlGaN are grown, by using metal organic chemical vapor deposition (MOCVD), on the growth substrate 11 made of a sapphire single crystal. Next, the mask 13 which is made of SiO₂ and has a film thickness of about 30 nm is deposited on the underlying layer 12 by a sputtering method, and the openings each having a diameter of about 150 nm are formed by using a fine pattern forming method such as nanoimprinting lithography. As growth conditions for the buffer layer, for example, trimethyl alminium (TMA), trimethyl gallium (TMG), and ammonia are used as raw material gases, a growth temperature is 1100° C., a V/III ratio is 1000, hydrogen is used as a carrier gas, and pressure is 10 hPa. As growth conditions for the underlying layer 12 and the n-type semiconductor layer, for example, a growth temperature is 1050° C., a V/III ratio is 1000, hydrogen is used as a carrier gas, and pressure is 500 hPa.

Next, in the nanowire growth step shown in FIG. 2B, the n-type nanowire layer 14 made of GaN is grown, by selective growth using a MOCVD method, on the underlying layer 12 exposed from each of the openings. As growth conditions for the n-type nanowire layer 14, for example, TMG and ammonia are used as raw material gases, a growth temperature is 1050° C., a V/III ratio is 10, hydrogen is used as a carrier gas, and pressure is 100 hPa.

Next, in the growth step shown in FIG. 2C, the active layer 15, the p-type semiconductor layer 16, and the tunnel junction layer 17 are sequentially grown on the side surface and the upper surface of the n-type nanowire layer 14 by using the MOCVD method. The active layer 15 is obtained by stacking the GaInN quantum well layer having the thickness of 5 nm and the GaN barrier layer having the thickness of 10 nm in the five cycles. The p-type semiconductor layer 16 is made of GaN doped with the p-type impurity. The tunnel junction layer 17 includes: the p+ layer which is made of GaN having the thickness of 5 nm and the Mg concentration of 2×10²⁰ cm⁻³; and the n+ layer which is made of GaN having the thickness of 10 nm and the Si concentration of 2×10²⁰ cm⁻³. Then, the buried semiconductor layer 18 made of n-type GaN is grown, and an outer periphery and the upper surface of the tunnel junction layer 17 are covered with the buried semiconductor layer 18. In incorporation in the active layer 15 will be described later.

As growth conditions for the active layer 15, for example, a growth temperature is 800° C., a V/III ratio is 3000, nitrogen is used as a carrier gas, pressure is 1000 hPa, and TMG, trimethyl indium (TMI), and ammonia are used as raw material gases. As growth conditions for the p-type semiconductor layer 16, for example, a growth temperature is 950° C., a V/III ratio is 1000, hydrogen is used as a carrier gas, pressure is 300 hPa, and TMG, bis-cycropentadienyl magnesium (Cp₂Mg), and ammonia are used as raw material gases. As described above, in order to stop the etching on the p-type semiconductor layer 16 when the removed region 19 is formed, it is preferable to increase the film thickness of the p-type semiconductor layer 16, and growth conditions for the p-type semiconductor layer 16 are also preferably conditions under which growth on a c-plane that is growth in a vertical direction is promoted. As growth conditions for the tunnel junction layer 17, for example, a growth temperature is 800° C., a V/III ratio is 3000, nitrogen is used as a carrier gas, and pressure is 500 hPa.

As described above, the buried semiconductor layer 18 needs to be grown on the mask 13 provided between the columnar semiconductor layers, and a void may be generated at a lower portion of each of the columnar semiconductor layers when the buried semiconductor layer 18 is grown. Therefore, it is preferable that the buried semiconductor layer 18 uses TMG, silane, and ammonia as raw material gases, and is grown in an initial stage at a low temperature and low V/III ratio at which growth on an m-plane that is lateral growth is promoted. Examples of the low temperature and low V/III ratio include conditions that a temperature is 800° C. or lower, a V/III ratio is 100 or less, hydrogen is used as a carrier gas, and pressure is 200 hPa.

After the mask 13 is covered without gap at the lower portion of the columnar semiconductor layer due to the lateral growth of the buried semiconductor layer 18, it is preferable to perform growth at a high temperature and high V/III ratio at which growth on a c-plane that is growth in the vertical direction is promoted. Examples of the high temperature and high V/III ratio include conditions that a temperature is 1000° C. or higher, a V/III ratio is 2000 or more, hydrogen is used as a carrier gas, and pressure is 500 hPa.

Then, in the removal step shown in FIG. 2D, a part of the buried semiconductor layer 18 and the tunnel junction layer 17 is selectively removed by dry etching and an upper surface of the p-type semiconductor layer 16 is exposed, thereby forming the removed region 19. In a region where the cathode electrodes 20 and 21 are to be formed, the mask 13 is removed to expose an upper surface of the underlying layer 12.

After the removal step, an activation step is performed of activating the p-type semiconductor layer 16 and the tunnel junction layer 17 by performing annealing at 600° C. in an air atmosphere and releasing hydrogen incorporated into the p-type semiconductor layer 16 and the p-type semiconductor layer in the tunnel junction layer 17. Here, the annealing in the air atmosphere is shown, but any atmosphere may be used as long as atomic hydrogen capable of activating the p-type semiconductor layer 16 and the tunnel junction layer 17 is not present.

Finally, in the electrode formation step shown in FIG. 2E, the cathode electrodes 20 and 21 are formed on the surface of the underlying layer 12, and the anode electrodes 22 and 23 are formed on the buried semiconductor layer 18. Annealing after electrode formation, formation of the passivation film, and element division are performed as necessary to obtain the semiconductor light emitting element 10.

In the semiconductor light emitting element 10 according to the present embodiment, when a voltage is applied between the cathode electrodes 20 and 21 and the anode electrodes 22 and 23, a current flows sequentially through the buried semiconductor layer 18, the tunnel junction layer 17, the p-type semiconductor layer 16, the active layer 15, the n-type nanowire layer 14, and the n-type semiconductor layer, and light is generated in the active layer 15 by the light emission recombination. The light emitted from the active layer 15 is extracted to an outside of the semiconductor light emitting element 10.

In the semiconductor light emitting element 10 according to the present embodiment, the active layer 15 is formed on the outer periphery of the n-type nanowire layer 14, and the tunnel junction layer 17 is further formed above the outer periphery of the active layer 15 and covered with the buried semiconductor layer 18. Therefore, the current injected from the anode electrodes 22 and 23 is injected from a side wall of the p-type semiconductor layer 16 into the active layer 15 as a tunnel current from the buried semiconductor layer 18 through the tunnel junction layer 17. A resistance of current injection of the tunnel current through the tunnel junction layer 17 is small, and the current injection can be performed favorably. Since the current is more easily to be diffused in the buried semiconductor layer 18 which is an n-type semiconductor layer than in a p-type semiconductor layer, the current can be favorably diffused to the side surface of the columnar semiconductor layer and a vicinity of a bottom surface, and the current can be injected from the entire tunnel junction layer 17.

As a result, the current injected from the anode electrodes 22 and 23 can be favorably injected into the p-type semiconductor layer 16 from the entire side surface rather than the upper surface of the columnar semiconductor layer, the current can be favorably injected into the active layer 15 to achieve a high current density, and external quantum efficiency can be improved.

Since the side surface of the n-type nanowire layer 14 is an m-plane formed by the selective growth, the active layer 15 and the p-type semiconductor layer 16 formed on the outer periphery of the n-type nanowire layer 14 are also in contact with each other on the m-plane. Since the m-plane is a nonpolar plane and polarization does not occur, light emission efficiency in the active layer 15 is also high, and since all of side surfaces of the hexagonal column are m-planes, light emission efficiency of the semiconductor light emitting element 10 can be improved. Furthermore, since a film thickness of the active layer can be increased, a volume of the active layer 15 can be increased to about 3 times to 10 times that of a semiconductor light emitting element in related art, and an injected carrier density can be reduced to significantly reduce efficiency droop.

The inventor of the present application has studied the mask 13 used for the selective growth when the n-type nanowire layer 14 is formed, and as a result, has found that by an opening ratio of the openings in a light emitting region and the growth conditions, a diameter, a height, a growth facet, and the like of the n-type nanowire layer 14 can be controlled, and incorporation of In into the active layer 15 formed on the outer periphery of the n-type nanowire layer 14 can be increased. Hereinafter, a method for increasing the In composition ratio of In incorporated into the active layer 15 so as to increase the light emission wavelength of the semiconductor light emitting element 10 will be described.

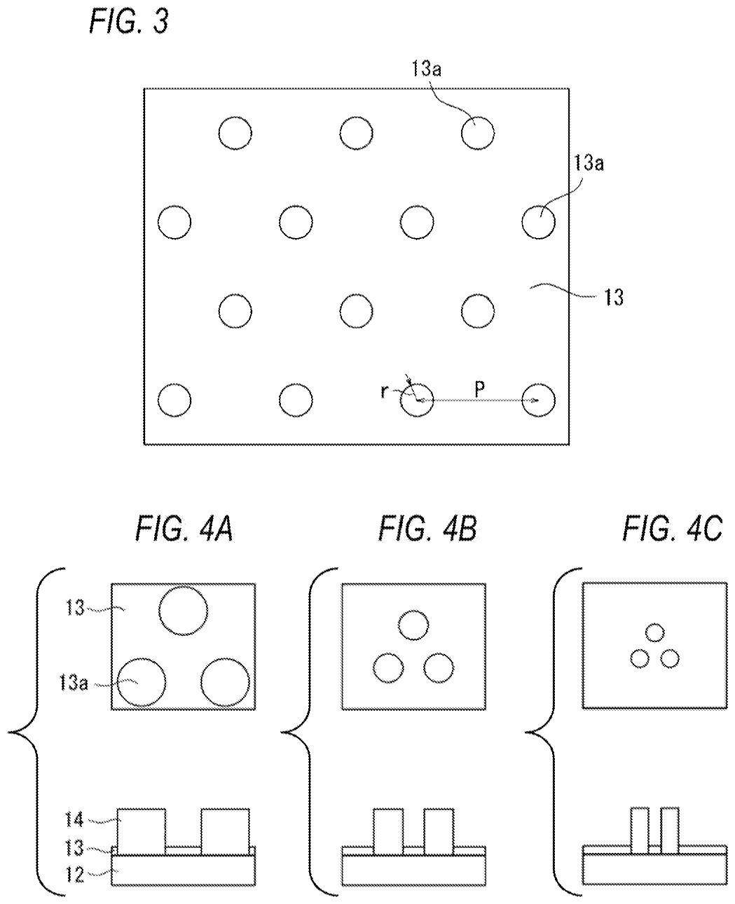

FIG. 3 is a schematic plan view showing a shape of the mask 13 formed in the light emitting region on the growth substrate 11 . As shown in the drawing, openings 13a are formed in a triangular lattice shape in the mask 13, and from each of the openings 13a, the underlying layer 12 is exposed and the n-type nanowire layer 14 can be selectively grown. The opening ratio of the openings 13a in the mask 13 is a ratio of openings 13a per unit area, and is determined by a radius r (opening diameter 2r) of the openings 13a and a distance (pitch p) between centers of adjacent openings 13a. The opening ratio (%) can be expressed by 2π/√3×(r/p)²×100 when the radius r and the pitch p of the openings 13a are used.

Next, a method for controlling a shape of the n-type nanowire layer 14 by the opening diameter (2r) and the pitch (p) of the openings 13a will be described with reference to FIGS. 4A to 8C. In FIGS. 4A to 8C, cases where the growth conditions such as a flow rate of a raw material, the pressure, and the growth temperature are the same when the n-type nanowire layer 14 is grown will be compared.

FIGS. 4A to 4C are schematic views showing a case where a ratio of the radius r and the pitch p of the openings 13a is constant and the radius r is changed, an upper part shows schematic plan views, and a lower part shows schematic sectional views. FIGS. 4A to 4C are the same in the ratio of the radius r and the pitch p of the openings 13a, and thus are also the same in the ratio of the openings 13a per the unit area and are also the same in the opening ratio. Since FIGS. 4A to 4C are the same in the opening ratio in the mask 13, FIGS. 4A to 4C are the same in total amount of the raw material supplied to all of the openings 13a, and are approximately the same in the height of the n-type nanowire layer 14. When FIGS. 4A to 4C are substantially the same in the opening ratio and the height, the larger a nanowire diameter is, the more easily In is incorporated into the active layer, and the longer the wavelength is.

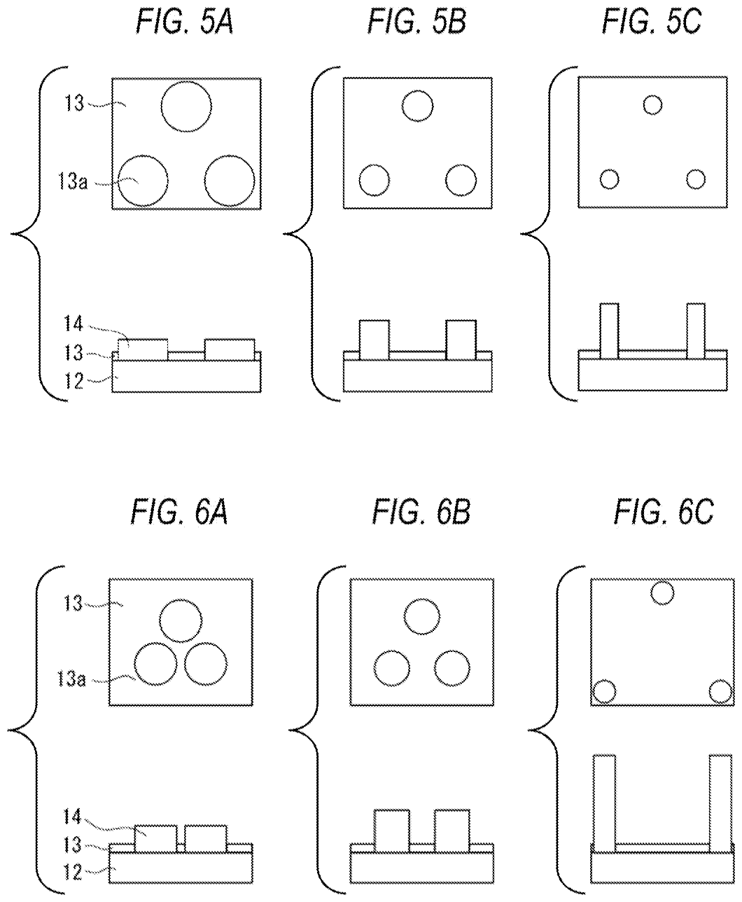

FIGS. 5A to 5C are schematic views showing a case where the pitch p of the openings 13a is constant and the radius r is changed, an upper part shows schematic plan views, and a lower part shows schematic sectional views. Since FIGS. 5A to 5C are the same in the pitch p, a relationship in magnitude of the opening ratio is determined by a size of the radius r, and the opening ratio increases in an order of FIG. 5A>FIG. 5B>FIG. 5C. Since FIGS. 5A to 5C are different in the opening ratio in the mask 13, FIGS. 5A to 5C are different in amount of the raw material supplied to one opening 13a and are also different in the height of the n-type nanowire layer 14, and the height decreases as the opening ratio increases. An incorporation amount of In also varies depending on a height of a nanowire. The lower the height of the nanowire is, the more easily In is incorporated, and the longer the wavelength is.

FIGS. 6A to 6C are schematic views showing a case where the pitch p and the radius r of the openings 13a are changed, an upper part shows schematic plan views, and a lower part shows schematic sectional views. In FIGS. 6A to 6C, as the pitch p is reduced and the radius r increases, the opening ratio increases, and the opening ratio increases in an order of FIG. 6A>FIG. 6B>FIG. 6C. Since FIGS. 6A to 6C are different in the opening ratio in the mask 13, FIGS. 6A to 6C are different in amount of the raw material supplied to one opening 13a and are also different in the height of the n-type nanowire layer 14, and the height decreases as the opening ratio increases. In an example shown in FIGS. 6A to 6C, since a difference in the opening ratio can be changed to be larger than that in FIGS. 5A to 5C, a difference in the height of the n-type nanowire layer 14 can be increased.

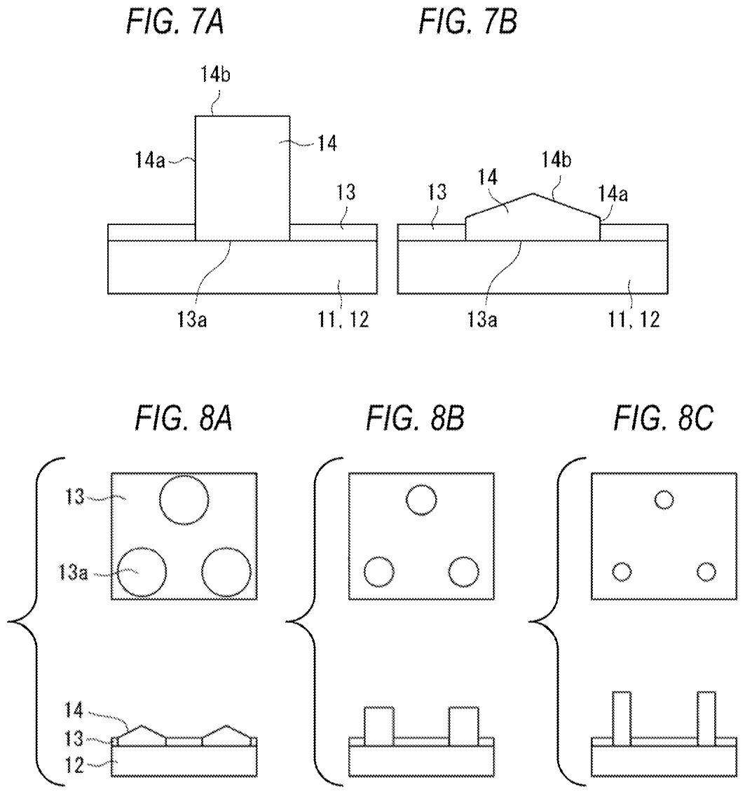

FIG. 7A and FIG. 7B are schematic sectional views each showing a facet constituting a surface of the n-type nanowire layer 14. FIG. 7A shows a case where a top surface is a c-plane, and FIG. 7B shows a case where the top surface is an r-plane. Crystal growth for the n-type nanowire layer 14 selectively grown from each of the openings 13a of the mask 13 continues upward with a side surface 14a as the m-plane. This is because in crystal growth of GaN, crystal growth in an r-plane direction or a c-plane direction is earlier than crystal growth in an m-plane direction. Therefore, a top surface 14b of the n-type nanowire layer 14 includes an r-plane or c-plane facet.

Whether the top surface 14b of the n-type nanowire layer 14 is the r-plane facet or the c-plane facet is determined by the growth conditions. Therefore, by changing the growth conditions at a stage of performing the crystal growth for an uppermost portion of the n-type nanowire layer 14, the facet of the top surface 14b can be controlled to be the c-plane or the r-plane. Specifically, the r-plane facet is easily formed in a case of a relatively low temperature and a high ammonia flow rate, and the c-plane facet is easily formed in a case of a relatively high temperature and a low ammonia flow rate. As an example, the r-plane is formed by growth at 980° C., and the c-plane is formed by growth at 1000° C.

As shown in FIG. 7B, it is also possible to shorten a growth time for the n-type nanowire layer 14 in a height direction, and to form a shape in which the m-plane is hardly exposed as the side surface 14a above the mask 13 and the r-plane facet is exposed from the opening 13a as the top surface 14b. In this case, the active layer 15 formed on the outer periphery of the n-type nanowire layer 14 is also formed on the r-plane.

FIGS. 8A to 8C are schematic views showing a case where the pitch p of the openings 13a is constant, the radius r is changed, and an r-plane facet is exposed as a top surface, an upper part shows schematic plan views, and a lower part shows schematic sectional views. Since FIGS. 8A to 8C are the same in the pitch p, a relationship in magnitude of the opening ratio is determined by a size of the radius r, and the opening ratio increases in an order of FIG. 8A>FIG. 8B>FIG. 8C. Since FIGS. 8A to 8C are different in the opening ratio in the mask 13,

FIGS. 8A to 8C are different in amount of the raw material supplied to one opening 13a and are also different in the height of the n-type nanowire layer 14, and the height decreases as the opening ratio increases. In FIG. 8A, similarly to FIG. 7B, after the n-type nanowire layer 14 is formed at such a height that the side surface thereof is not exposed, the r-plane facet is formed as the top surface.

Next, a tendency of In incorporation when the active layer 15 containing In is formed, by crystal growth, on the outer periphery of the n-type nanowire layer 14 will be described. When the active layer 15 of GaInN is grown on the outer periphery of the n-type nanowire layer 14, it is necessary to consider whether the n-type nanowire layer 14 extends in the height direction and whether an In raw material gas supplied from above can be favorably supplied to the entire side surface.

As shown in the lower parts of FIGS. 4A to 4C, when the opening ratio is the same and the radius of the opening 13a is large, the pitch p is also large, and a space present between the adjacent n-type nanowire layers 14 is large. As a result, an In raw material can be sufficiently supplied to a lower side on the side surface of the n-type nanowire layer 14, and the In composition in the active layer 15 formed on the m-plane of the side surface can be increased. However, when the radius of the opening 13a is reduced, the pitch p is reduced, and the space present between the adjacent n-type nanowire layers 14 is made small. As a result, the In raw material is blocked by the n-type nanowire layer 14, In is less likely to be incorporated into the active layer 15 formed on the side surface of the n-type nanowire layer 14, and the In composition ratio decreases. This is because In is shorter in movement distance than other materials in the MOCVD method.

When the radius r and the pitch p of the openings 13a are the same, the higher the n-type nanowire layer 14 is in height, the more easily the In raw material is blocked by an upper portion of the n-type nanowire layer 14, and it is difficult to supply the In raw material to a lower portion of the n-type nanowire layer 14. As described above, the lower the n-type nanowire layer 14 is in height, the more easily the In composition ratio in the active layer 15 on the side surface is increased.

When the radius r of the openings 13a is the same, the pitch p is changed, and the height of the n-type nanowire layer 14 is the same, the space present between the adjacent n-type nanowire layers 14 becomes small as the pitch p is reduced, and it becomes difficult to supply the In raw material to the lower portion of the n-type nanowire layer 14 because of blocking of the In raw material by the upper portion. As described above, the larger the pitch p of the openings 13a is, the more easily the In composition ratio in the active layer 15 on the side surface is increased.

In crystal growth of GaInN, a ratio of incorporated In is different depending on a growth plane, and In is more easily incorporated onto the r-plane formed on the top surface than onto the m-plane that is the side surface of the n-type nanowire layer 14. Therefore, as shown in FIG. 7B, the side surface of the n-type nanowire layer 14 is not exposed above the mask 13, and the r-plane facet which is the top surface is exposed, so that the ratio of In in the active layer 15 formed on the top surface as the r-plane by the crystal growth can be increased.

As described above, the semiconductor light emitting element 10 has a structure in which a current is injected into the active layer 15 from the side surface of the n-type nanowire layer 14 by using the tunnel junction layer 17. Therefore, as shown in FIG. 7A, in the n-type nanowire layer 14 including the side surface and the top surface, a portion of the active layer 15 formed on the side surface mainly emits light. Therefore, by increasing the In composition ratio in the active layer 15 on the side surface, it is possible to achieve the increase in light emission wavelength and to emit light at a long wavelength of 480 nm or more.

As shown in FIG. 7B, in the n-type nanowire layer 14 that includes the r-plane facet as the top surface and whose side surface is hardly exposed, a portion of the active layer 15 formed on the top surface mainly emits light. Therefore, by increasing the In composition ratio in the active layer 15 on the top surface, it is possible to achieve the increase in light emission wavelength and to emit light at a wavelength in a red region.

As described above, under conditions that the radius r of the openings 13a increases, the pitch p increases, the n-type nanowire layer 14 is lowered, and the r-plane facet is used, the In composition ratio in the active layer 15 formed on the outer periphery of the n-type nanowire layer 14 can be increased, and the wavelength can be increased. However, influences of the blocking of the In raw material by the n-type nanowire layer 14, a size of the space present between the adjacent n-type nanowire layers 14, the ratio of incorporated In based on the growth plane, and the like are related to each other. Therefore, in fact, the tendency of the In composition ratio in the active layer 15 is different from that in a case where each of the above parameters is independently changed.

### Examples

Manufacturing Examples 1 to 5 and 6 to 10 are created by using the manufacturing method shown in FIGS. 2A to 2E and setting the same growth conditions for the n-type nanowire layer 14 and the active layer 15, and the light emission wavelength is measured. The light emission wavelength is measured by cathode luminescence measurement using a SEM device (SU70 manufactured by Hitachi High-Technologies Corporation). Results are shown in Table 1. Manufacturing Examples 1 to 5 and Manufacturing Examples 6 to 10 are the same in opening diameter and the pitch of the openings 13a respectively, and are different in In vapor phase ratio when the active layer 15 is grown. Manufacturing Examples 1 to 3 and 6 to 7 are comparative examples, and Manufacturing Examples 4 to 5 and 8 to 10 are examples.

TABLE 1

| | | | | | In vapor | |
|---|---|---|---|---|---|---|
| | Opening | | Opening | | phase ratio | Height (nm) |
| | diameter | Pitch | ratio | Wavelength | In/(Ga + In) | of n-GaN |
| | (nm) | (nm) | (%) | (nm) | (%) | nanowire |
| Manufacturing Example 1 | 400 | 1200 | 10.1 | 431 | 85 | 800 |
| Manufacturing Example 2 | 230 | 880 | 6.2 | 433 | 85 | 850 |
| Manufacturing Example 3 | 150 | 800 | 3.2 | 463 | 85 | 900 |
| Manufacturing Example 4 | 100 | 700 | 1.9 | 480 | 85 | 1000 |
| Manufacturing Example 5 | 50 | 600 | 0.6 | 550 | 85 | 1100 |
| Manufacturing Example 6 | 400 | 1200 | 10.1 | 466 | 92 | 900 |
| Manufacturing Example 7 | 230 | 880 | 6.2 | 462 | 92 | 950 |
| Manufacturing Example 8 | 150 | 800 | 3.2 | 502 | 92 | 1050 |
| Manufacturing Example 9 | 100 | 700 | 1.9 | 525 | 92 | 1100 |
| Manufacturing Example 10 | 50 | 600 | 0.6 | 590 | 92 | 1200 |

FIG. 9 is a graph showing experimental results of Manufacturing Examples 1 to 10, and shows a relationship between the opening ratio of the openings 13a and the light emission wavelength. As shown in FIG. 9, the light emission wavelength can be increased as the opening ratio becomes small. In the graph, square plots indicate Manufacturing Examples 1 to 5, and circular plots indicate Manufacturing Examples 6 to 10. Each curve in the graph is obtained by approximating the respective plots by a least square method. In the approximate curve of Manufacturing Examples 6 to 10, the light emission wavelength is 480 nm when the opening ratio is 0.05 (5.0%), and the light emission wavelength is 500 nm when the opening ratio is 0.03 (3.0%).

Therefore, it can be seen that by setting the opening ratio of the openings 13a of the mask 13 to 0.05 (5.0%) or less, the In composition in the active layer 15 formed on the outer periphery of the side surface of the n-type nanowire layer 14 can be increased, and light can be emitted at a long wavelength of 480 nm or more. It can be seen that by setting the opening ratio of the openings 13a of the mask 13 to 0.03 (3.0%) or less, the In composition in the active layer formed on the outer periphery of the side surface of the n-type nanowire layer 14 can be increased, and light can be emitted at a long wavelength of 500 nm or more.

With reference to Manufacturing Examples 1 to 5 and 6 to 10 shown in Table 1, it can be seen that the wavelength increases as the opening diameter is reduced, the wavelength increases as the pitch is reduced, and the wavelength increases as the n-type nanowire layer 14 becomes high in height. It is considered that this is because when the same growth conditions are set, the opening ratio affects the height of the n-type nanowire layer 14 and affects a proportion of the top surface to the surface of the n-type nanowire layer 14.

As previously shown in FIGS. 5A to 5C, as the opening ratio increases, the formed n-type nanowire layer 14 is lowered. When the radius r of the openings 13a increases and the n-type nanowire layer 14 is lowered, the proportion of the top surface to the surface of the n-type nanowire layer 14 increases. In is more easily incorporated onto the r-plane or c-plane facet formed on the top surface than onto the m-plane. As a result, it is considered that when the proportion of the top surface is large, the In raw material supplied during the growth of the active layer 15 is incorporated onto the top surface and is difficult to be supplied to the side surface, and the In composition ratio in the side surface of the active layer 15 becomes small.

It is considered that this is because the In raw material is more easily blocked by the n-type nanowire layer 14 as the n-type nanowire layer 14 becomes high in height, and there is an influence that it is difficult to supply the In raw material to the side surface, but an influence of In incorporation on the top surface is larger. When the opening ratio is about 10% or less, a sufficient space is ensured between the adjacent n-type nanowire layers 14, so that it is considered that an influence of blocking of the In raw material by the n-type nanowire layer 14 is small.

Therefore, as shown in Table 1 and FIG. 9, in order to increase the In composition ratio in the active layer 15 formed on the outer periphery of the n-type nanowire layer 14, it can be said that the opening ratio is most important. In order to set the light emission wavelength to 480 nm or more, the In composition in the active layer 15 is preferably in a range of 0.10 or more and 0.40 or less. In order to reduce the In incorporation onto the top surface, the opening diameter (2r) of the openings 13a is preferably 100 nm or more and 200 nm or less, and in order to maintain the opening ratio at the time of the opening diameter, the pitch is preferably 400 nm or more and 850 nm or less. The height of the n-type nanowire layer 14 is preferably 1000 nm or more and 2000 nm or less.

As shown in FIG. 7B, when the active layer 15 is formed by not exposing the side surface of the n-type nanowire layer 14 and exposing the r-plane facet which is the top surface, In is easily incorporated onto the r-plane which is a semipolar plane, so that it is also possible to emit red light by increasing the In composition ratio in the active layer 15 to about 0.4.

As described above, in the semiconductor light emitting element 10 according to the present embodiment, the opening ratio of the openings 13a formed in the mask 13 is set in a range of 0.1% or more and 5.0% or less, so that the ratio of In incorporated into the active layer 15 can be increased by controlling the height, the diameter, and the crystal growth plane of the n-type nanowire layer 14 under the same growth conditions, and light can be emitted at 480 nm or more with high reproducibility.

### Second Embodiment

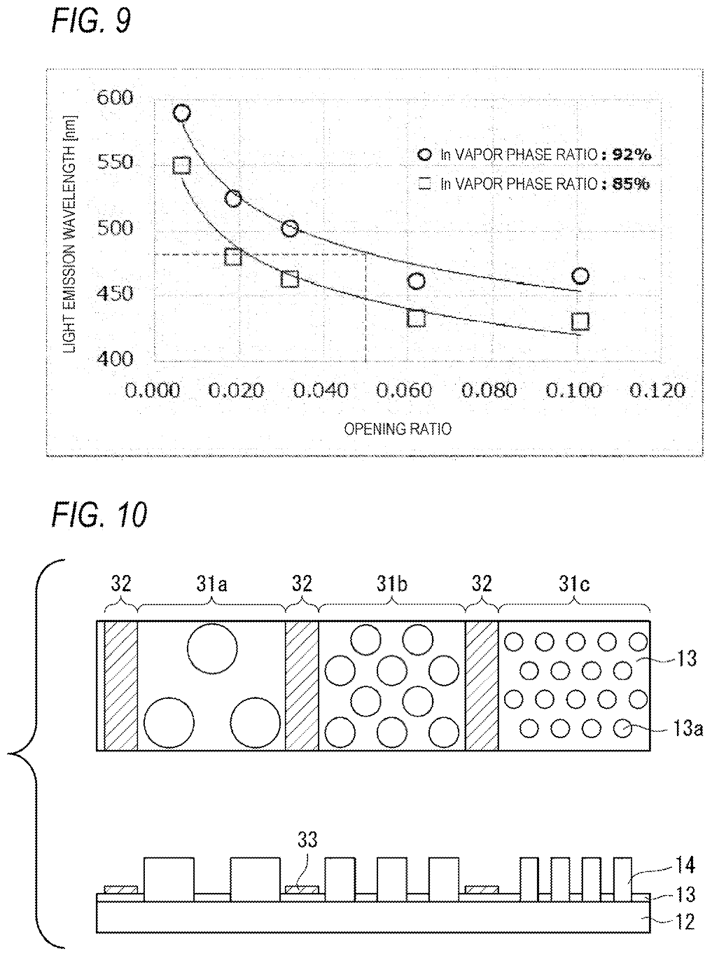

Next, a second embodiment of the present disclosure will be described with reference to FIG. 10. Descriptions of the same contents as those of the first embodiment will be omitted.

In the present embodiment, a plurality of light emitting regions are provided on the growth substrate 11, and the n-type nanowire layer 14 and the active layer 15 are collectively and monolithically formed in each of the plurality of light emitting regions.

FIG. 10 is schematic views showing the light emitting regions of the semiconductor light emitting element 10 according to the present embodiment, an upper part in FIG. 10 is a schematic plan view, and a lower part in FIG. 10 is a schematic sectional view. As shown in FIG. 10, the plurality of light emitting regions are provided on the growth substrate 11 and the underlying layer 12, and are separated, as a first region 31a, a second region 31b, and a third region 31c, by isolation regions 32. A wiring pattern 33 is formed on the mask 13 in each of the isolation regions 32. The mask 13 and the openings 13a are formed in each of the first region 31a, the second region 31b, and the third region 31c, and the regions are different in opening ratio of the openings 13a.

The isolation regions 32 are regions in which no opening 13a is formed and which are provided between adjacent two of the first region 31a, the second region 31b, and the third region 31c different in opening ratio, and each of the isolation regions 32 has a width of 10 μm or less. A reason why the width of the isolation region 32 is set to 10 μm or less is that when the n-type nanowire layer 14 and the active layer 15 are selectively grown, raw materials supplied onto the mask 13 can be moved by about 5 μm. When the isolation region 32 has the width of 10 μm or less, the raw materials that reach a center of the isolation region 32 move to the opening 13a and are used for selective growth, and it is possible to prevent the raw materials from precipitating as a polycrystal or the like on the mask 13.

The wiring pattern 33 is a pattern formed of metal or the like on the isolation region 32, and extends to an outside in FIG. 10 to electrically connect the cathode electrodes 20 and 21 with the outside of the semiconductor light emitting element 10. The wiring pattern 33 may be formed of a material different from that of the cathode electrodes 20 and 21, or may be collectively formed of the same material as that of the cathode electrodes 20 and 21.

When each wiring pattern 33 is independently formed for a respective one of the first region 31a, the second region 31b, and the third region 31c, a current can be supplied to the active layer 15 included in the respective one of the first region 31a, the second region 31b, and the third region 31c, and the first region 31a, the second region 31b, or the third region 31c can selectively emit light. When the wiring pattern 33 is formed as a wiring common to the first region 31a, the second region 31b, and the third region 31c, light can be emitted by simultaneously supplying a current to the first region 31a, the second region 31b, and the third region 31c.

In an example shown in FIG. 10, the first region 31a, the second region 31b, and the third region 31c are different in the radius r and the pitch p of the openings 13a, and are the same in opening ratio and the same in height of the formed n-type nanowire layer 14 similarly to FIGS. 4A to 4C. However, as shown in FIGS. 5A to 5C, FIGS. 6A to 6C, and FIGS. 8A to 8C, the first region 31a, the second region 31b, and the third region 31c may be different in opening ratio depending on the radius r and the pitch p of the openings 13a.

In the present embodiment, since the first region 31a, the second region 31b, and the third region 31c are collectively and monolithically formed on the same growth substrate 11, the regions are necessarily the same in growth conditions for the n-type nanowire layer 14 and the active layer 15. In the present disclosure, as shown in FIG. 9, even under the same growth conditions, the In composition in the active layer 15 can be changed by changing the opening ratio. As a result, the first region 31a, the second region 31b, and the third region 31c are different from each other in the light emission wavelength in the active layer 15.

In particular, as shown in FIGS. 8A to 8C, in any one of the first region 31a, the second region 31b, and the third region 31c, the side surface of the n-type nanowire layer 14 is not exposed, and only the r-plane which is the semipolar plane of the top surface is exposed. Therefore, the In composition ratio in the active layer 15 formed on the top surface can be increased to about 40%, thereby emitting red light. By using, as the other two regions among the first region 31a, the second region 31b, and the third region 31c, a region in which the opening ratio of the openings 13a is 0.1% or more and 5.0% or less, and a region in which the opening ratio of the openings 13a is more than 5.0%, blue-green light of 480 nm or more and blue light of less than 480 nm can be emitted respectively from the regions.

Furthermore, when the opening ratio of the openings 13a is set to 0.1% or more and 3.0% or less, green light of 500 nm can be emitted, so that the blue light, the green light, and the red light can be emitted from the first region 31a, the second region 31b, and the third region 31c, respectively. Light of respective colors of RGB are emitted by arranging the semiconductor light emitting elements 10 on the growth substrate 11 in a shape of a matrix, and individually supplying currents to the first region 31a, the second region 31b, and the third region 31c by the wiring patterns 33, so that it is possible to constitute an image display device in which each semiconductor light emitting element 10 is one pixel. RGB can be emitted by simultaneously supplying the current to the first region 31a, the second region 31b, and the third region 31c by the common wiring pattern 33, so that it is also possible to constitute an illumination device that emits white light.

### Third Embodiment

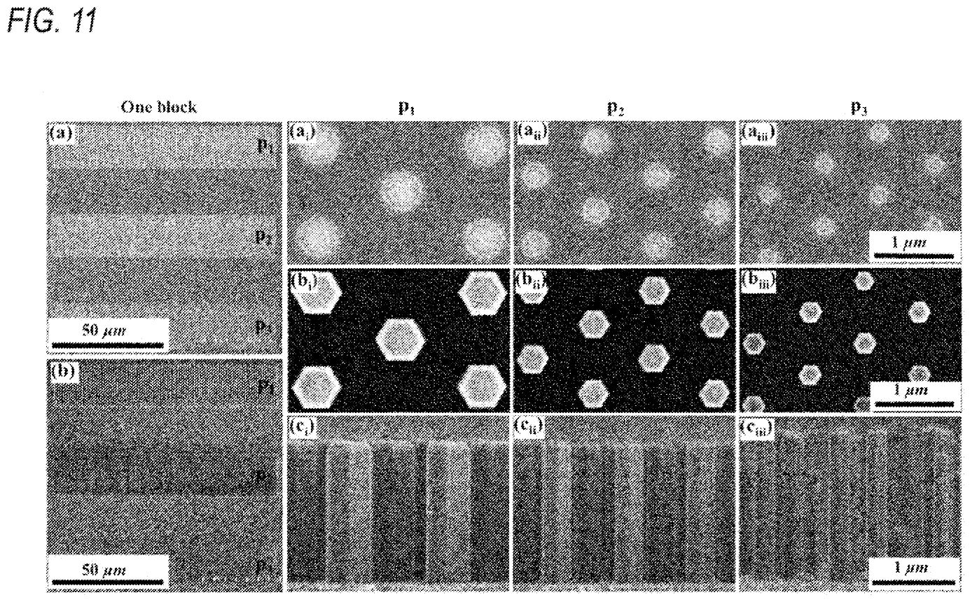

Next, a third embodiment of the present disclosure will be described with reference to FIGS. 11 to 15. Descriptions of the same contents as those of the first embodiment will be omitted. FIG. 11 is SEM images showing crystal growth for the n-type nanowire layer 14 when the openings 13a having different opening diameters are formed in a plurality of regions on the same growth substrate 11.

An image labeled (a) in FIG. 11 is a planar-view SEM image showing a state where the openings 13a are formed by electron beam exposure, an opening diameter is 400 nm and a pitch is 1200 nm in a region P1, an opening diameter is 230 nm and a pitch is 880 nm in a region P2, and an opening diameter is 150 nm and a pitch is 800 nm in a region P3. The regions P1, P2, and P3 each have a width of 20 μm and a length of 100 μm, and intervals between adjacent regions are each 20 μm. Images labeled (ai) to (aiii) in FIG. 11 are enlarged planar-view SEM images each showing the openings 13a formed in a respective one of the regions P1, P2, and P3.

An image labeled (b) in FIG. 11 is a planar-view SEM image showing a state after the n-type nanowire layer 14 is selectively grown. Images labeled (bi) to (biii) in FIG. 11 are enlarged planar-view SEM images each showing the n-type nanowire layer 14 formed in a respective one of the regions P1, P2, and P3, and Images labeled (ci) to (ciii) in FIG. 11 are cross-sectional SEM images.

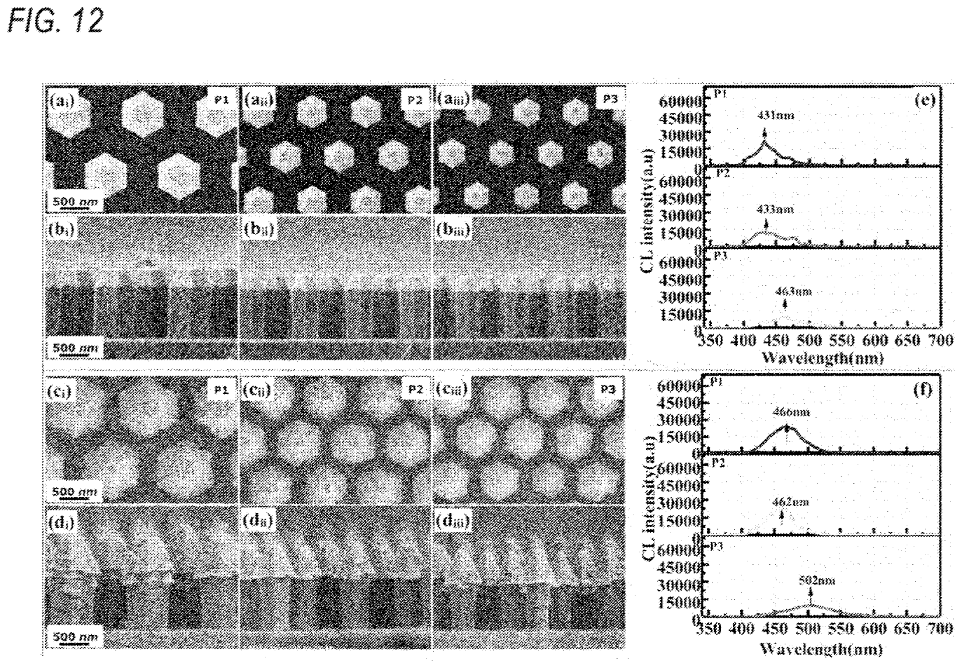

FIG. 12 is SEM images and results of cathode luminescence measurement showing a state where a GaInN/GaN multiple quantum well structure is formed as the active layer 15 on the outer periphery of the n-type nanowire layer 14. A growth temperature for a well layer is 750° C., and a growth temperature for a barrier layer is 750° C. Images labeled (ai) to (aiii) in FIG. 12, images labeled (bi) to (biii) in FIG. 12, and an image labeled (e) in FIG. 12, which are shown in an upper part in FIG. 12, show a case where a flow rate of triethylgallium (TEG) that is a Ga raw material is 30 sccm. Images labeled (ci) to (ciii) in FIG. 12, images labeled (di) to (diii) in FIG. 12, and an image labeled (f) in FIG. 12, which are shown in a lower part in FIG. 12, show a case where a flow rate of TEG that is a Ga raw material is 60 sccm.

Images labeled (ai) to (aiii) in FIG. 12 and images labeled (ci) to (ciii) in FIG. 12 are enlarged planar-view SEM images each showing the active layer 15 formed in a respective one of the regions P1, P2, and P3. Images labeled (bi) to (biii) in FIG. 12 and Images labeled (di) to (diii) in FIG. 12 are enlarged cross-sectional SEM images each showing the active layer 15 formed in a respective one of the regions P1, P2, and P3. Images labeled (e) and (f) in FIG. 12 are spectral diagrams showing the results of cathode luminescence (CL) measurement using a SEM device.

As shown in FIG. 12, a light emission wavelength obtained by the CL measurement increases as the opening ratio of the openings 13a becomes small. The light emission wavelength increases by increasing the flow rate of TEG even when the opening ratio is the same. Due to an increase in the flow rate of TEG, a region having a high In composition is formed in a vicinity of a top portion.

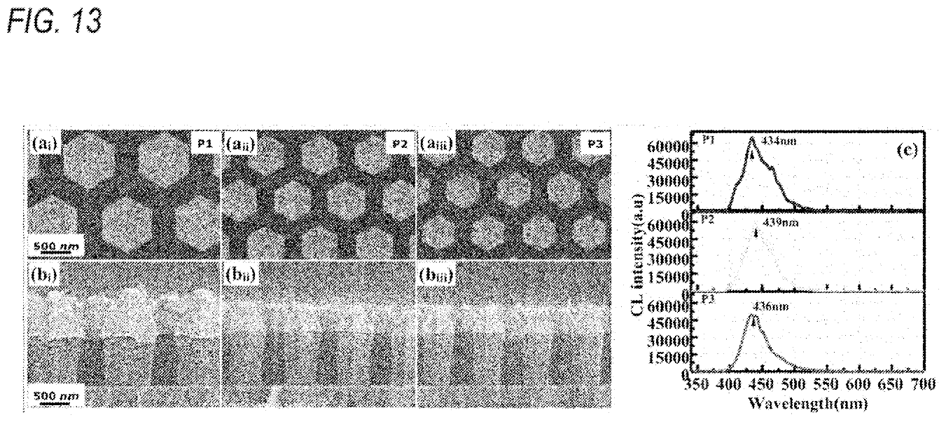

FIG. 13 is SEM images and a result of cathode luminescence measurement when a GaN barrier layer in the active layer 15 is grown at 800° C. The growth temperature for the well layer is 750° C., and the flow rate of TEG is 60 sccm. Images labeled (ai) to (aiii) in FIG. 13 are enlarged planar-view SEM images each showing the active layer 15 formed in a respective one of the regions P1, P2, and P3, and images labeled (bi) to (biii) in FIG. 13 are cross-sectional SEM images.

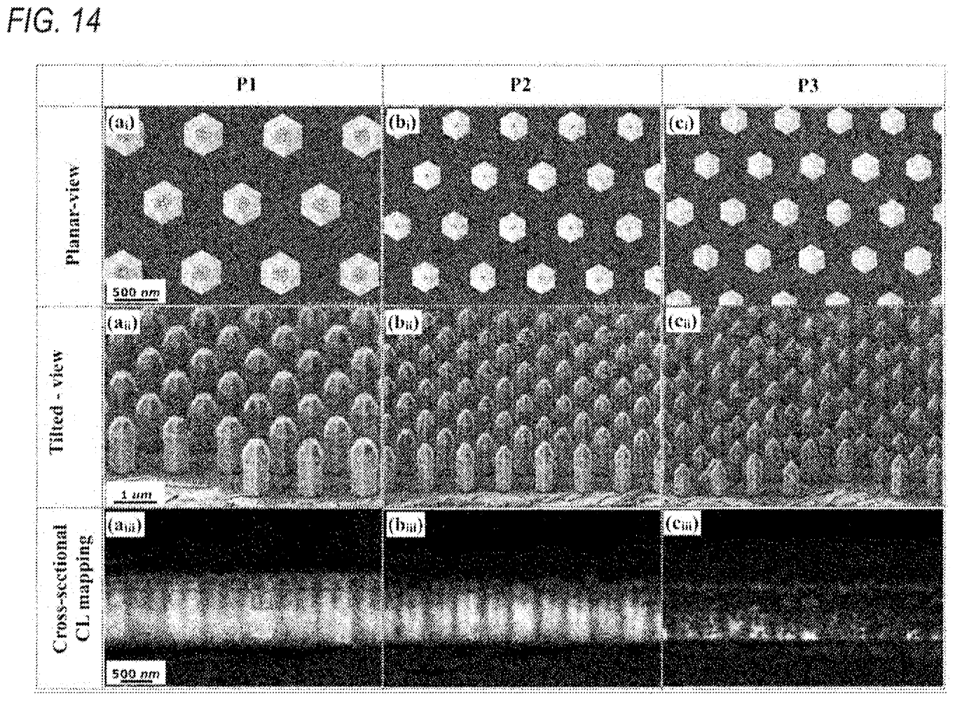

FIG. 14 is SEM images and results of cathode luminescence mapping when a GaInN well layer in the active layer 15 is grown at 730° C. Images labeled (ai) to (aiii) in FIG. 14 are enlarged planar-view SEM images each showing the active layer 15 formed in a respective one of the regions P1, P2, and P3, and Images labeled (bi) to (biii) in FIG. 14 are tilted-view SEM images. Images labeled (ci) to (ciii) in FIG. 14 are total light CL images of cross sections of the regions P1, P2, and P3.

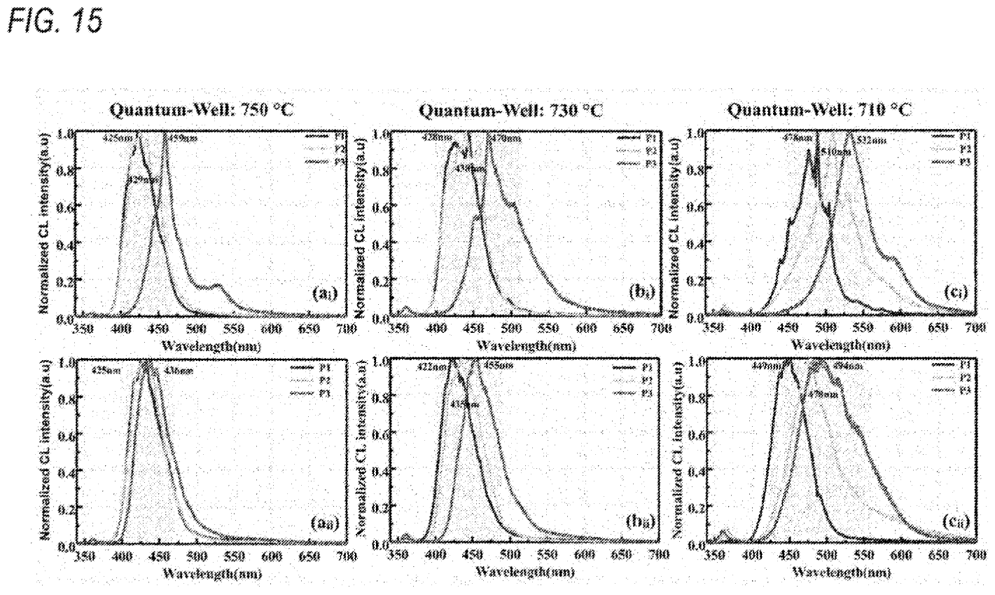

FIG. 15 is graphs showing normalized CL intensities when growth temperatures of the GaInN well layer are 750° C., 730° C., and 710° C. The growth temperature for the barrier layer is 800° C., and the flow rate of TEG is 30 sccm. Images labeled (ai) in FIG. 15, an image labeled (bi) in FIG. 15, and an image labeled (ci) in FIG. 15 which are shown in an upper part in FIG. 15 show measurement results in the vicinity of the top portion of the n-type nanowire layer 14, and an image labeled (aii) in FIG. 15, an image labeled (bii) in FIG. 15, and an image labeled (cii) in FIG. 15 which are shown in a lower part in FIG. 15 show measurement results at the lower portion of the n-type nanowire layer 14.

As shown in FIG. 15, it can be seen that in the vicinity of the top portion of the n-type nanowire layer 14, a CL peak wavelength is longer than that at the lower portion, and an In incorporation amount is larger than that at the lower portion. It can be seen that the lower the growth temperature for the GaInN well layer is, the longer the CL peak wavelength is, and the more easily In is incorporated.

The present invention is not limited to the embodiments described above, various modifications can be made within the scope of the claims, and embodiments obtained by appropriately combining technical means disclosed in the different embodiments are also included in the technical scope of the present invention.

The present application is based on Japanese Patent Application No. 2020-145488 filed on Aug. 31, 2020, and the contents of which are incorporated herein by reference.

1. A semiconductor light emitting element comprising:
a growth substrate;
a mask formed on the growth substrate; and
a columnar semiconductor layer grown from at least one opening that is provided in the mask,
wherein the columnar semiconductor layer includes an n-type nanowire layer formed at a center thereof, an active layer formed on an outer periphery of the n-type nanowire layer, and a p-type semiconductor layer formed on an outer periphery of the active layer, and
wherein an opening ratio of the opening is 0.1% or more and 5.0% or less, and a light emission wavelength is 480 nm or more.

2. The semiconductor light emitting element according to claim 1,
wherein the opening ratio is 0.1% or more and 3% or less, and the light emission wavelength is 500 nm or more.

3. The semiconductor light emitting element according to claim 1,
wherein an In composition ratio in the active layer is in a range of 0.10 or more and 0.40 or less.

4. The semiconductor light emitting element according to claim 1,
wherein a height of the n-type nanowire layer is 1000 nm or more and 2000 nm or less, and
wherein an opening diameter of the opening is 100 nm or more and 200 nm or less, and a pitch is 400 nm or more and 850 nm or less.

5. The semiconductor light emitting element according to claim 1,
wherein the n-type nanowire layer includes a semipolar plane, and the active layer is formed on the semipolar plane.

6. A semiconductor light emitting element comprising:
a growth substrate;
a mask formed on the growth substrate; and
a columnar semiconductor layer grown from each of openings that are provided in the mask,
wherein the columnar semiconductor layer includes an n-type nanowire layer formed at a center thereof, an active layer formed on an outer periphery of the n-type nanowire layer, and a p-type semiconductor layer formed on an outer periphery of the active layer,
wherein in a first region of the growth substrate, an opening ratio of the opening is 0.1% or more and 5.0% or less, and a light emission wavelength is 480 nm or more, and
wherein in a second region of the growth substrate, an opening ratio of the opening is more than 5.0%, and a light emission wavelength is less than 480 nm.

7. A semiconductor light emitting element comprising:
a growth substrate;
a mask formed on the growth substrate; and
a columnar semiconductor layer grown from each of openings that are provided in the mask,
wherein the columnar semiconductor layer includes an n-type nanowire layer formed at a center thereof, an active layer formed on an outer periphery of the n-type nanowire layer, and a p-type semiconductor layer formed on an outer periphery of the active layer,
wherein in a first region of the growth substrate, an opening ratio of the opening is a first opening ratio,
wherein in a second region of the growth substrate, an opening ratio of the opening is a second opening ratio, and
wherein the first opening ratio is smaller than the second opening ratio, and a light emission wavelength in the first region is longer than that in the second region.

8. A semiconductor light emitting element comprising:
a growth substrate;
a mask formed on the growth substrate; and
a columnar semiconductor layer grown from each of openings that are provided in the mask,
wherein the columnar semiconductor layer includes an n-type nanowire layer formed at a center thereof, an active layer formed on an outer periphery of the n-type nanowire layer, and a p-type semiconductor layer formed on an outer periphery of the active layer, and
wherein the openings in a first region and the openings in a second region of the growth substrate are the same in opening ratio and different in opening diameter and pitch, and the first region and the second region are the same in height of the n-type nanowire layer.

9. The semiconductor light emitting element according to claim 6,
wherein an isolation region having a width of 10 μm or less is provided between the first region and the second region, and
wherein a wiring pattern is formed on the mask in the isolation region.

10. The semiconductor light emitting element according to claim 6,
wherein in the first region, the second region, or a third region of the growth substrate, the n-type nanowire layer includes a semipolar plane, and the active layer is formed on the semipolar plane.

11. A method for manufacturing a semiconductor light emitting element, the method comprising:
a mask step of forming, on a growth substrate, a mask layer including an opening; and
a growth step of forming a columnar semiconductor layer in the opening by using selective growth,
wherein the growth step includes a step of forming an n-type nanowire layer, a step of forming an active layer on an outer side of the n-type nanowire layer, and a step of forming a p-type semiconductor layer on an outer side of the active layer, and
wherein in the mask step, an opening ratio of the opening is set in a range of 0.1% or more and 5.0% or less.
